(19) United States
(12) Patent Application Publication
(10) Pub. No.: US 2026/0305496 A1
(43) Pub. Date: Oct. 1, 2026

(54) TCDRAM DEVICE ASSEMBLY AND METHOD THEREOF

(71) Applicant: Micron Technology, Inc., Boise, ID (US)

(72) Inventor: Jungbae Lee, Taichung (TW)

(21) Appl. No.: 19/558,134

(22) Filed: Mar. 5, 2026

Related U.S. Application Data
(60) Provisional application No. 63/781,270, filed on Mar. 31, 2025.

(51) Int. Cl. H10W 90/00; H10B 80/00

(52) U.S. Cl. CPC H10W 90/732; H10B 80/00; H10W 90/7295

(57) ABSTRACT

A semiconductor device assembly is disclosed. The semiconductor device assembly includes a substrate, one or more memory devices disposed on the substrate, and a bulk material layer disposed on the substrate, the bulk material surrounding vertical edges of each of the one or more memory devices. The semiconductor device assembly also includes an insulating layer disposed between the one or more memory devices and the surrounding bulk material layer, and a semiconductor layer disposed on the one or more memory devices and the bulk material layer, the semiconductor layer is bonded with the one or more memory devices through a bonding interface layer. The semiconductor device assembly further includes a plurality of micro bumps disposed on the semiconductor layer.

### CROSS-REFERENCE TO RELATED APPLICATIONS

The present application claims priority to U.S. Provisional Patent Application No. 63/781,270, filed Mar. 31, 2025, the disclosure of which is incorporated herein by reference in its entirety.

### TECHNICAL FIELD

The present disclosure generally relates to semiconductor device assemblies, and more particularly relates to 3D stacked memory device assemblies involving integration of logic dice and memory dice in a semiconductor device package.

### BACKGROUND

The integration of memory devices and logic devices within a single semiconductor device assembly is driven by the need for enhanced performance, reduced latency, and increased energy efficiency in modern computing systems. This integration aims to address the growing demand for faster data processing and higher bandwidth in applications ranging from high-performance computing to mobile devices. Methods for achieving this integration include the use of advanced packaging techniques such as 2.5D and 3D stacking, where memory and logic dice are placed in close proximity or stacked vertically. Interposers and through-silicon vias (TSVs) are also commonly employed to facilitate high-density interconnections between the dice, ensuring efficient communication and data transfer.

3D stacked memory devices integrate logic dice and memory devices such as high-bandwidth memory (HBM) dice to meet the specification for high-performance computing and data-intensive applications. An advanced 3D stacked memory device is assembled, through precise alignment and bonding of the dice, to achieve faster data transfer rates, reduced latency, and improved energy efficiency, which are critical for applications such as artificial intelligence, machine learning, and real-time data processing.

### BRIEF DESCRIPTION OF THE DRAWINGS

FIG. 1 shows a cross-section view of a semiconductor device assembly in accordance with various embodiments of the present technology.

FIGS. 2-9 illustrate stages of fabricating a semiconductor device assembly in accordance with various embodiments of the present technology.

FIG. 10 shows a top down view of a semiconductor device assembly in accordance with various embodiments of the present technology.

FIG. 11 shows a top down view of another semiconductor device assembly in accordance with various embodiments of the present technology.

FIG. 12 shows a method flow of semiconductor device assembly in accordance with various embodiments of the present technology.

FIG. 13 is a schematic block diagram of a system that includes a semiconductor device assembly configured in accordance with one or more embodiments of the present technology.

### DETAILED DESCRIPTION

3D stacked memory is designed to integrate logic dice and memory dice within a single, cohesive semiconductor device assembly to enhance performance and efficiency. Advanced 3D stacked memory devices utilize high-density and high-performance memory devices such as HBM, which is stacked in multiple layers to provide a large amount of memory capacitance. In addition, logic dice of 3D stacked memory devices are designed to work seamlessly with HBM, ensuring minimal latency and high-speed data transfer. Generally, the assembly of 3D stacked memory includes advanced packaging techniques such as 2.5D and 3D stacking. In 2.5D stacking, the logic and memory dice are placed side by side on an interposer, which acts as a bridge, connecting the dice with high-density interconnects. It also provides a high-density interconnection pathway to ensure efficient communication between the memory and logic dice. With this technology, the device assembly method allows for efficient communication and data transfer between the logic and memory components while maintaining a relatively simple assembly process. The interposer also helps in managing signal integrity and power distribution. In 3D stacking, the dice are stacked vertically and interconnected using TSVs, further reducing the distance between the logic and memory components and enhancing data transfer speeds.

While the conventional 3D stacked memory assembly technologies have been established, they face several limitations when dealing with high-performance applications. For example, in 2.5D packaging, the high-density interconnections of logic and memory dice on the interposer can lead to signal integrity issues such as crosstalk and electromagnetic interference (EMI). These issues can degrade the performance of the 3D stacked memory by causing data errors and reducing the reliability of communication between the dice. Additionally, ensuring signal integrity requires careful design and layout of the interposer, which can increase the complexity and cost of the manufacturing process. The interposer and the dice are subject to mechanical stress and strain during the assembly process, and the production of silicon interposers with high-density interconnects is expensive. In another example, the assembly of memory and logic dice in a 3D stacked configuration requires precise alignment to ensure reliable electrical connections through the TSVs. Any misalignment can lead to connectivity issues and affect the overall performance of the device. The fabrication of TSVs and the integration of multiple dice require advanced manufacturing techniques. This can increase the complexity and cost of production, making it challenging to achieve high yields and cost-effective manufacturing. As semiconductor devices continue to scale, there is a growing need for innovative solutions that can overcome these limitations and support the advancement of 3D stacked memory applications.

To solve the issues and challenges described above, the present technology introduces an innovative semiconductor device assembly suitable for 3D stacked memory device packaging. The present technology involves patterning cavities on a backside surface of a logic wafer and then bonding one or more memory or storage devices into the logic wafer cavities. Specifically, the logic wafer substrate is etched to expose its frontside surface functional semiconductor layer which contains functional components of the logic wafer. Memory dice are directly bonded on the exposed semiconductor layer within the cavities, forming an integrated logic die-memory die assembly. To ensure dielectric insulation, the gaps next to the memory dice in the cavities of the logic wafer are filled by dielectric insulating materials. Additionally, micro bumps can be fabricated onto the semiconductor layer of the logic wafer to facilitate signal communication. This technology enables a short signal path between the logic die and the corresponding memory die by hybrid bonding the memory die directly onto the functional surface layer of the logic wafer. Furthermore, the structure and functions associated with memory die signal routing, such as redistribution (RDL) layers and signal routing layers, can be integrated into the surface semiconductor layer of the logic wafer. This semiconductor device assembly enhances the memory die capacity and overall performance of the device.

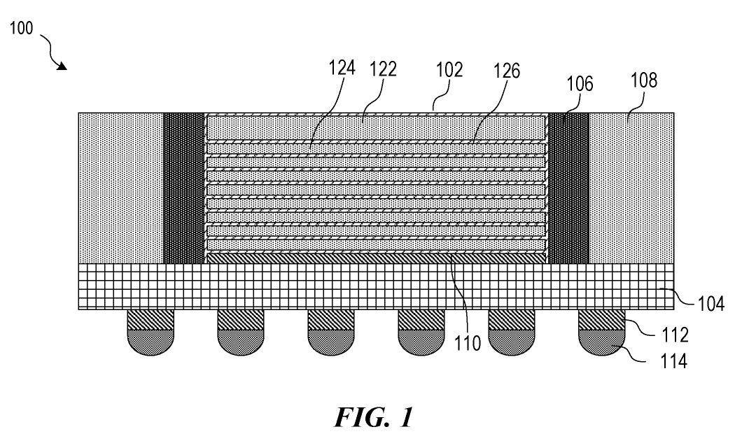

FIG. 1 shows a cross-section view of a semiconductor device assembly 100 in accordance with various embodiments of the present technology. In one embodiment, the semiconductor device assembly 100 can be a 3D stacked memory device. For example, the semiconductor device assembly 100 includes one or more memory devices (e.g., one or more HBM cubes 102) and a semiconductor layer 104. As shown, the HBM cube 102 includes a plurality of memory dice 124 that are vertically stacked. Each of the plurality of memory dice 124 is bonded by a corresponding conductive bonding layer 126 to adjacent memory dice. Here, the conductive bonding layer 126 provides signal transmission between the stacked memory dice 124 and mechanical stability to bond the stacked memory dice 124 together. The HBM cube 102 may include a thicker memory die 122 disposed on top of the stack and configured for structural integrity, mechanical support, and heat dissipation.

In this embodiment, the semiconductor layer 104 can be originally formed on a frontside surface of a logic wafer and fabricated to contain semiconductor devices such as transistor and passive devices such as capacitors, inductors, and resistors. The semiconductor layer 104 can be fabricated using conventional semiconductor manufacturing front-end-of-line (FEOL) and back-end-of-line (BEOL) processes. Further, the semiconductor layer 104 can include redistribution (RDL) layers or signal routing layers (not shown in FIG. 1), which are configured for signal routing and power distribution among the memory dice and the semiconductor layer 104. For example, the signal routing layers can provide necessary interconnect pathways to route signals, such as data signal, address signal, and control signal, passing through the stacked memory dice 124 and from the HBM cube 102 to the semiconductor layer 104. In addition, RDLs can facilitate the distribution of power and ground connections across the semiconductor layer 104 and the HBM cube 102. In this embodiment, the functions of RDL layers and signal routing layers may replace that of the bottom memory die embedded in traditional HBM cubes. In another word, the present technology transfers the necessary RDL layers and signal routing layers from the HBM cube to an adjacent semiconductor layer, enhancing the memory capacity of the semiconductor device assembly 100.

As shown in FIG. 1, the HBM cube 102 is bonded on the semiconductor layer 104 through a bonding interface layer 110. Here, a hybrid boding process can be involved including forming electrical interconnects between contact metal pads and surrounding dielectric materials (with dielectric-dielectric bonds) for electrical isolation and structure support for the interconnects. With regards to memory dice involved in the HBM cube 102, various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, non-volatile NAND memory and others. Typically, the HBM cube 102 includes 4, 8, 12, 16, or 24 memory dice depending on the generation and specific design. A thickness of the HBM cube 102 may be up to 700µm. In some embodiments, the thickness of the HBM cube 102 can be higher and following relevant Joint Electron Device Engineering Council (JEDEC) specifications.

In this embodiment, a bulk material layer 108 is disposed on the semiconductor layer 104. As shown, the bulk material layer 108 surrounds the HBM cube 102, forming a gap that is filled by an insulating layer 106. The insulating layer 106 is configured to provide dielectric isolation between the HBM cube 102 and surrounding bulk material layer 108, and can be made of materials including silicon dioxide, silicon nitride, silicon carbide, silicon oxycarbide, silicon oxynitride, high-K dielectric materials, or a combination thereof. In this example, the HBM cube 102, the bulk material layer 108, as well as the insulating layer 106 have an overlapping flat top surface. In some other embodiments, the insulating layer 106 can overflow above the HBM cube 102 and the bulk material layer 108, with a top flat surface.

In this embodiment, the semiconductor layer 104 can be originally fabricated on a surface of a logic wafer substrate (e.g., using FEOL and/or BEOL semiconductor manufacturing processes). The bulk material layer 108 can be a portion of the logic wafer substrate. For example, the bulk material layer 108 shown in FIG. 1 can be formed through backside thinning of a logic wafer and pattern etching processes. Here, the bulk material layer can be made of materials comprising silicon, germanium, gallium arsenide, silicon carbide, gallium nitride, and III-V semiconductors.

As shown in FIG. 1, the semiconductor device assembly 100 further includes under bump metallization layers 112 and micro bumps 114. Each one of the micro bumps 114 are interconnected with the semiconductor layer 104 through corresponding under bump metallization layer 112. In particular, each of the under bump metallization layers 112 can be a multilayer stack including an adhesion layer, a barrier layer, and a wetting layer. The micro bumps 114 can be fabricated by depositing solder material on the under bump metallization layers 112 and then reflowing to form molten solders. In this embodiment, the micro bumps 114 provide high density electrical interconnections between an outer circuit and the bonded HBM cube 102 and semiconductor layer 104. The micro bumps 114 can be made of materials including titanium, chromium, nickel, titanium tungsten, copper, gold, or their alloys.

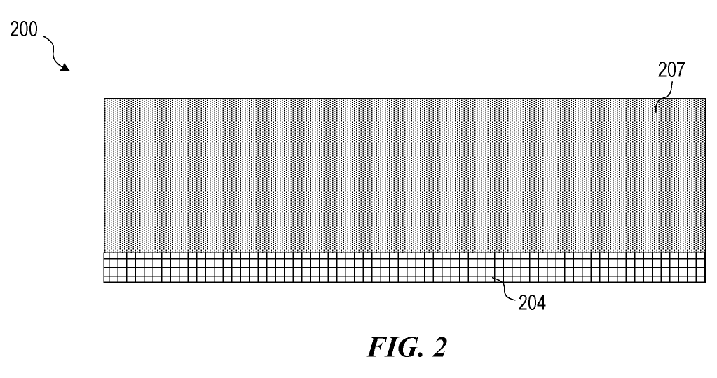

FIGS. 2-9 illustrate stages of fabricating a semiconductor device assembly in accordance with various embodiments of the present technology. The assembly process starts from providing a logic wafer 200. As shown in FIG. 2, the logic wafer has a substrate 207 and a functional semiconductor layer 204 disposed on a frontside surface of the logic wafer 200. The functional semiconductor layer 204 can be processed using conventional semiconductor manufacturing FEOL and BEOL processes. It may contain semiconductor devices such as transistor and passive devices such as capacitors, inductors, and resistors. The functional semiconductor layer 204 may also contain RDL layers or signal routing layers. Here, the logic wafer substrate 207 may be made of semiconductor bulk materials and have a thickness close to standard industry silicon wafer thickness, e.g., 775µm.

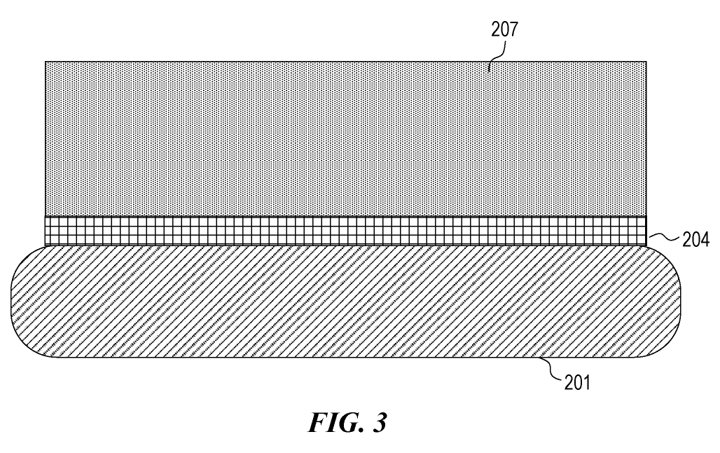

In a next step, the logic wafer 200 can be bonded to a carrier wafer 201. As shown in FIG. 3, the functional semiconductor layer 204 can be bonded to the carrier wafer 201, through a frontside to frontside (F2F) fusion bonding process. In this process, the frontside surface of the functional semiconductor layer 204 can be bonded with the frontside surface of the carrier wafer 201, without an intermediate adhesive layer. Necessary wafer surface preparation processes such as cleaning, planarization, and/or surface activation can be utilized to form a flat interface between the functional semiconductor layer 204 and the carrier wafer 201.

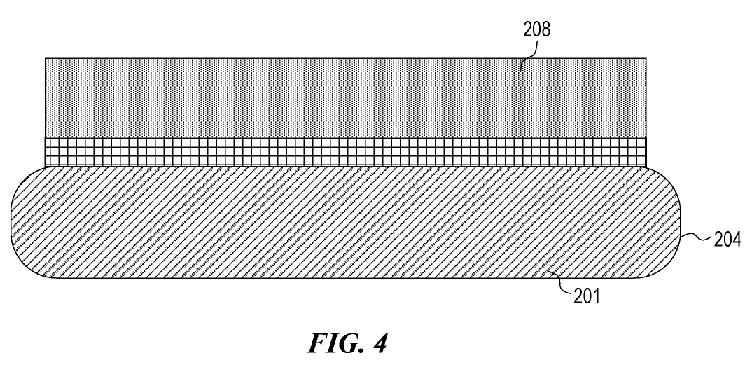

After the fusion bonding process, the logic wafer 200 will be thinned down. As shown in FIG. 4, a wafer backside thinning process can be conducted, from the backside of the logic wafer 200, on the substrate 208. Various technologies can be used in this step to reduce the thickness of the logic wafer substrate 208, including wafer grinding, chemical-mechanical polishing (CMP), plasma etching, or a combination thereof. The goal is to achieve a target thickness on the thinned logic wafer substrate 208. Ideally, the target thickness is similar to a height of HBM cube which will be bonded on the logic wafer 200 later in the semiconductor device assembly process. In some embodiments, the thinned logic wafer substrate has a thickness ranging from 500µm to 700µm. In some other embodiments, the thinned logic wafer substrate has a thickness close to 1000µm.

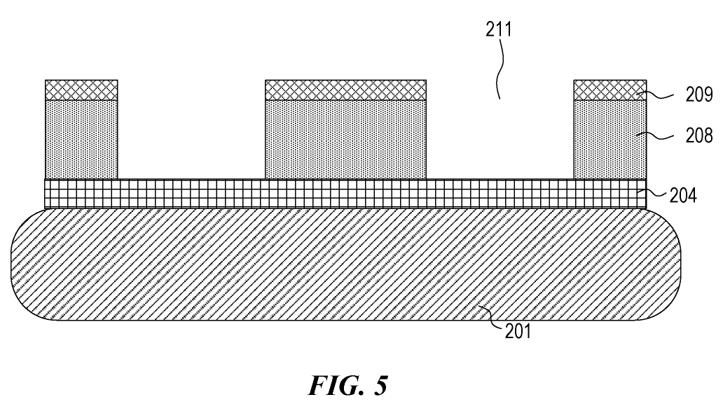

FIG. 5 shows a step of forming cavities in the logic wafer 200. In this step, the thinned logic wafer substrate 208 can be patterned using a photoresist layer 209 and lithography techniques. A chemical dry etching or a plasma etching process can be utilized to vertically etch the logic wafer substrate 208 and form cavities 211 therein. As shown in FIG. 5, the cavity etching stops at the functional semiconductor layer 204 of the logic wafer 200, which can be done by an end-detecting control or selective etching control of the etching process. Specifically, the cavity etching exposes the functional semiconductor layer 204, making it ready for a direct HBM cube bonding process in a downstream flow. Ideally, each of the cavities 211 has vertical sidewalls as shown in FIG. 5. In some other embodiments, the cavities 211 has tilted sidewalls, forming an inverted trapezoid shape. In this step, each of the cavities 211 has a planar dimension larger than a corresponding HBM cube. For example, to prepare for a bonding with HBM cube in 10mm x 10mm, the corresponding logic die embedded in the functional semiconductor layer 204 may have a size of 30mm x 25mm and the cavity may have a horizontal dimension of 11mm x 11mm. In the present technology, there maybe one or more logic dice disposed in the functional semiconductor layer 204 and underneath each of the cavities 211.

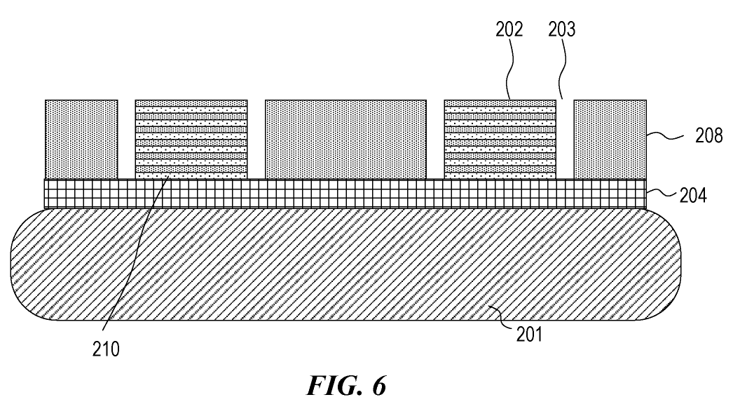

Once the logic wafer cavities are formed, one or more memory devices or storage devices (such as HBM cubes 202) can be implemented, e.g., through hybrid bonding to the functional semiconductor layer 204, into corresponding cavities. The hybrid bonding process may include forming contact pads and filling composite bonding material surrounding the bonded contact pads. Further, the hybrid bonding process may also include a thermal anneal process in elevated temperatures. In this example, the one or more memory devices or storage devices can be connected to the functional semiconductor layer 204 by a chip to wafer bonding (C2W) technique in a front to back (F2B) configuration. As shown in FIG. 6, a bonding interface layer 210 is formed at the bonding interface between the HBM cubes 202 and the functional semiconductor layer 204. In addition, a RDL layer can also be formed between each of the one or more memory devices and the functional semiconductor layer 204. Here, the intercommunication between the memory devices and underneath functional semiconductor layer can be conducted through the bonding layer and/or the redistribution layer.

In other examples, the one or more memory devices or storage devices can be interconnected to the functional semiconductor layer 204 using TSVs or micro bump pillars. The pillar-based interconnection could enable high data bandwidth and improve power efficiency for date flow and communications. FIG. 6 also shows gaps 203 formed between the HBM cubes 202 and surrounding logic wafer substrate 208. In addition, the HBM cubes 202 and the thinned logic wafer substrate 208 may have a similar thickness, e.g., ranging from 500µm to 700µm. The gaps 203 may have a width ranging from 0.5mm to 1mm.

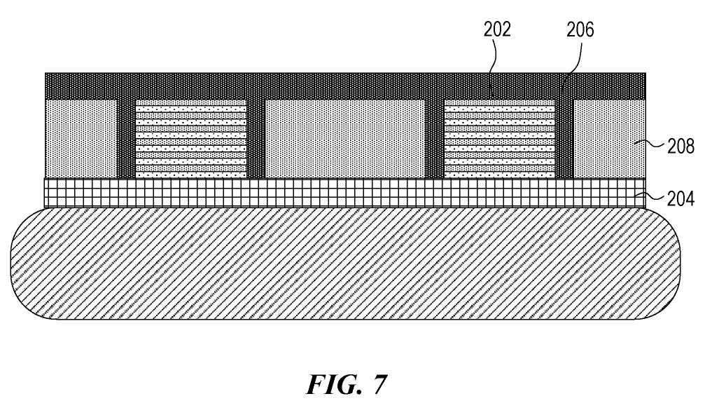

In a next step shown in FIG. 7, dielectric insulating material 206 can be filled in the gaps 203. Various techniques like Chemical Vapor Deposition (CVD), spin coating, and liquid underfill can be used for the gap filing. The insulating material 206 can made of materials comprising silicon dioxide, silicon nitride, silicon carbide, silicon oxycarbide, silicon oxynitride, high-K dielectric materials, or a combination thereof. As shown, there may be an overflow during the gap fill process, forming a continuous insulating layer above the HBM cubes 202 and logic wafer substrate 208. Additionally, the HBM cubes 202 have edges that are perpendicular to the functional semiconductor layer 204. As shown, semiconductor bulk materials of the logic wafer substrate 208 surrounds the edges of the HBM cubes 202.

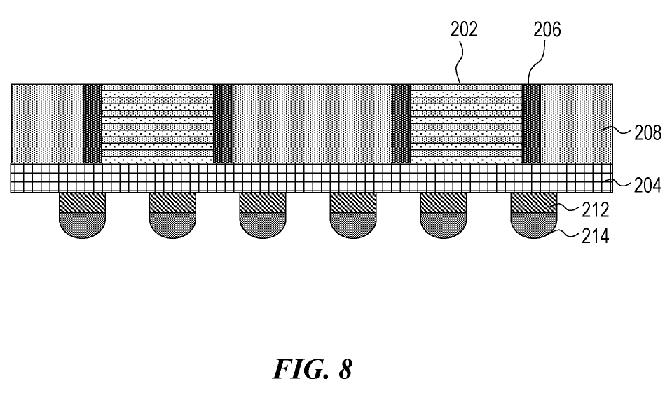

In the next step, as shown in FIG. 8, the carrier wafer can be removed from the semiconductor device assembly. In addition, a wafer grinding process or a CMP process can be adopted to polish the backside surface of the logic wafer 200. This process will form a flat surface above the logic wafer substrate and the HBM cubes. Moreover, the under bump metallization layers 212 and micro bumps 214 can be formed under the functional semiconductor layer 204 for electrical interconnection. Specifically, physical vapor deposition (PVD), sputtering, or electroplating processes, as well as photoresist application and patterning processes can be used to form the under bump metallization layers 212. A solder material deposition and a reflow process can be conducted to form the micro bumps 214 on corresponding under bump metallization layers 212.

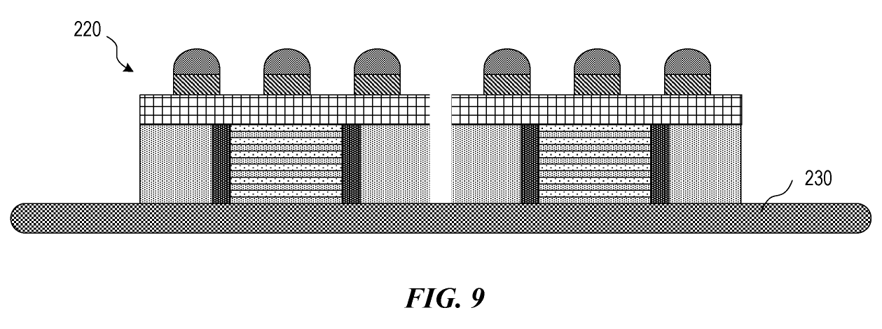

In the last step shown in FIG. 9, wafer singulation can be conducted, e.g., on the backside surface of the logic wafer substrate 208, to form individual bonded memory-logic dice 220. In this example, each of the bonded memory-logic dice 220 includes a single HBM cube and one or more logic dice. In some other example, multiple HBM cubes can be bonded with corresponding one or more logic dice, within a single cavity of the logic wafer substrate. After wafer singulation process, the carrier wafer 201 can be removed. The singulated memory-logic dice can be further mounted on a substrate 230 for additional semiconductor device assembly in downstream processes. For example, a molding material can be coated on the semiconductor device assembly to encapsulate the bulk material of the logic wafer substrate 208 and the functional semiconductor layer 204.

The present technology provides various embodiments in bonding one or more HBM cubes with logic dice. In one embodiment, one HBM cube can be directly bonded to one logic die of a semiconductor layer, similar to the semiconductor device assembly 100 shown in FIG. 1. Alternatively and in some other embodiments, multiple HBM cubes can be bonded to one or more logic dice of a semiconductor layer, for semiconductor device assembly.

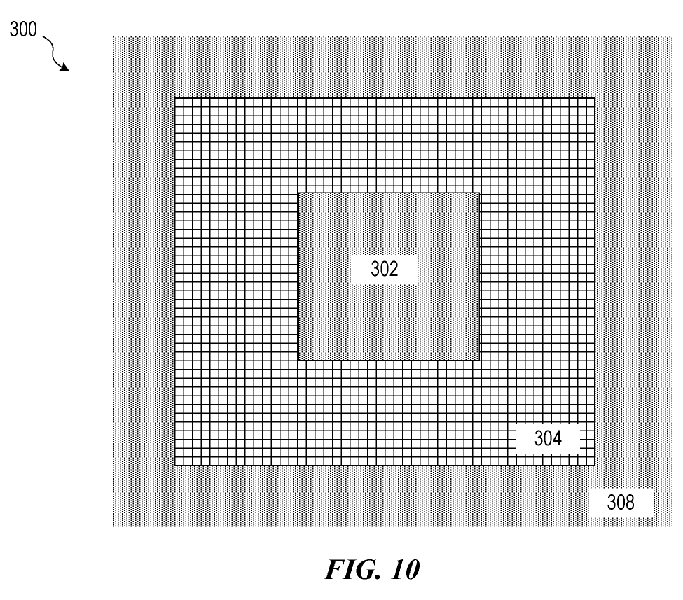

FIG. 10 shows a top down view of a semiconductor device assembly 300 in accordance with various embodiments of the present technology. In particular, the semiconductor device assembly 300 includes a single HBM cube 302 bonded on a functional semiconductor layer 304, within a cavity formed in a logic wafer substrate 308. Similar to the semiconductor device assembly 100 described earlier, a cavity can be processed on a backside of the logic wafer substrate 308, exposing its frontside functional semiconductor layer 304. The single HBM cube 302 can be implemented into the logic wafer substrate 308, i.e., through a hybrid bonding process to bond the bottom surface of the HBM cube 302 with the frontside functional semiconductor layer 304. This configuration forms a 1:1 HBM cube – logic die bonding scheme.

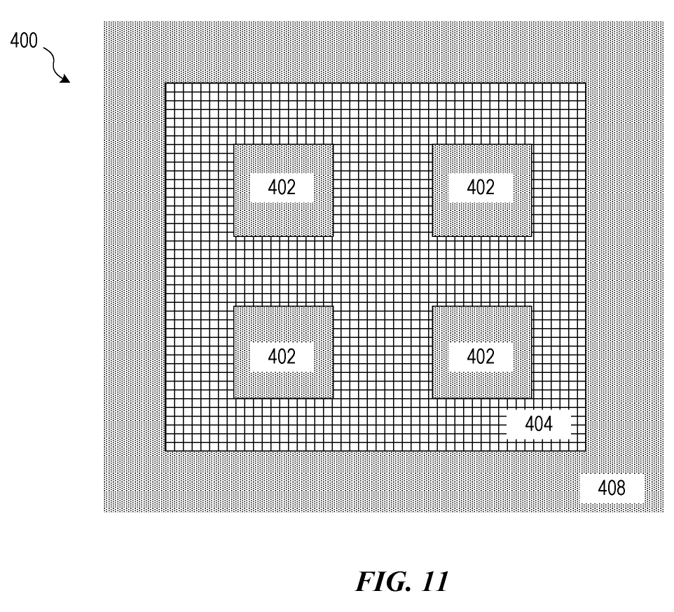

In another embodiment, FIG. 11 shows a top down view of another semiconductor device assembly 400 in accordance with various embodiments of the present technology. Here, multiple HBM cubes 402 can be bonded on a single logic die of a functional semiconductor layer 404. For example, the multiple HBM cubes 402 can be implemented into a single cavity of the logic wafer substrate 408, i.e., through a hybrid bonding process to bond all of the HBM cubes 402 to the frontside functional semiconductor layer 404. This configuration forms a N:1 HBM cube – logic die bonding scheme. In these embodiments, the formation of logic wafer cavity and hybrid bonding of HBM cubes therein can be similar to the semiconductor device assembly processes described in FIGS. 2-9. The bonding of multiple HBM cubes with a single logic die provides advantaged over a conventional configuration of a single HBM cube per logic die. For example, the multiple HBM cubes configuration can provide a higher memory bandwidth and higher memory capacity. In addition, the configuration of single logic die handling multiple HBM cubes can reduce the need for duplicating the logic circuitry across multiple logic dice, resulting in a more compact and efficient system design. Further, the multiple HBM cubes configuration could help achieving higher power efficiency and lower cost. In some other embodiments, multiple HBM cubes can be bonded with a number of logic dice of a semiconductor layer, forming a N:M HBM cube – logic die bonding scheme.

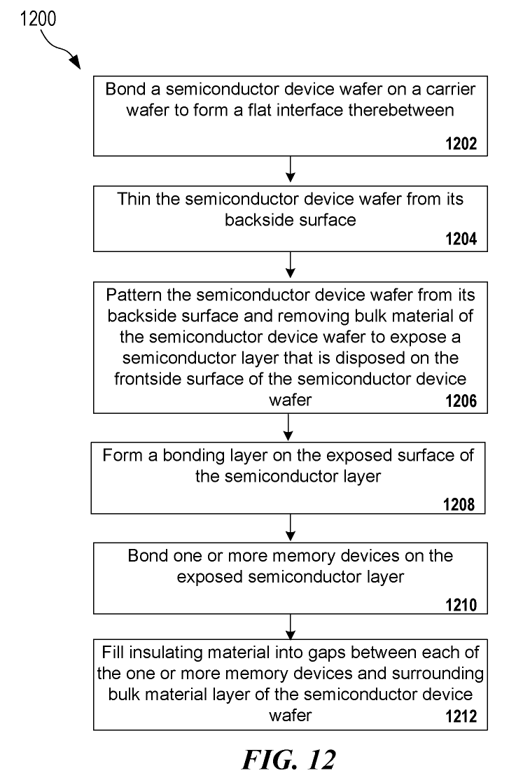

FIG. 12 shows a flow of method 1200 of semiconductor device assembly in accordance with various embodiments of the present technology. For example, the method 1200 includes bonding a semiconductor device wafer on a carrier wafer to form a flat interface therebetween, the semiconductor device wafer having a frontside surface facing towards the carrier wafer, at 1202. For example, the logic wafer 200 can be bonded on a carrier wafer 201. As shown in FIG. 3, the front side surface of the semiconductor layer 204 can be bonded to the frontside surface of the carrier wafer 201.

The method 1200 also includes thinning the semiconductor device wafer from its backside surface, at 1204. For example, the wafer backside thinning process can be conducted on the logic wafer substrate 207, as shown in FIG. 4, to achieve a proper logic wafer substrate thickness similar to corresponding HBM cubes.

In addition, the method 1200 includes patterning the semiconductor device wafer from its backside surface and removing bulk material of the semiconductor device wafer to expose a semiconductor layer that is disposed on the frontside surface of the semiconductor device wafer, at 1206. For example, cavities 211 are fabricated using patterning and etching processes on the backside surface of the logic wafer substrate 208, as shown in FIG. 5. In this step, the cavity etching process stops on the functional semiconductor layer 204, exposing it for the downstream memory die bonding process.

The method 1200 also includes forming a bonding layer on the exposed surface of the semiconductor layer, at 1208. For example, the bonding layer 210 is formed on exposed surface of the functional semiconductor layer 204 after the logic wafer cavities 211 are formed.

The method 1200 further includes bonding one or more memory devices on the exposed semiconductor layer, at 1210. For example, HBM cubes 202 can be bonded to the functional semiconductor layer 204 within corresponding cavities, through a hybrid bonding process, as described in FIG. 6.

Lastly, the method 1200 includes filling insulating material into gaps between each of the one or more memory devices and surrounding bulk material layer of the semiconductor device wafer, at 1212. For example, insulating material 206 can be filled into the gaps 203 and overflow above the logic wafer substrate 208, as shown in FIG. 7.

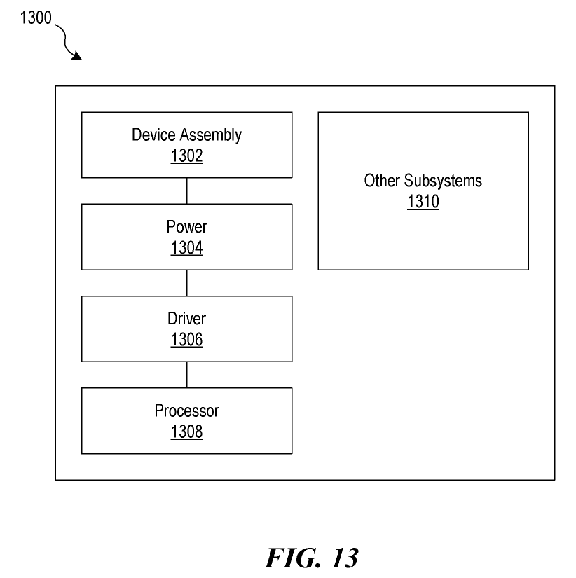

Any one of the semiconductor die assembly technology described above with reference to FIGS. 1-12 can be incorporated into any of a myriad of larger and/or more complex systems, a representative example of which is system 1300 shown schematically in FIG. 13. The system 1300 can include a semiconductor device assembly (e.g., or a discrete semiconductor device) 1302, a power source 1304, a driver 1306, a processor 1308, and/or other subsystems or components 1310. The semiconductor device assembly 1302 can include features generally similar to those of the semiconductor device assembly described above with reference to FIGS. 1-12. The resulting system 1300 can perform any of a wide variety of functions, such as memory storage, data processing, and/or other suitable functions. Accordingly, representative systems 1300 can include, without limitation, hand-held devices (e.g., mobile phones, tablets, digital readers, and digital audio players), computers, vehicles, appliances and other products. Components of the system 1300 may be housed in a single unit or distributed over multiple, interconnected units (e.g., through a communications network). The components of the system 1300 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate;
one or more memory devices disposed on the substrate;
a bulk material layer disposed on the substrate, the bulk material surrounding vertical edges of each of the one or more memory devices;
an insulating layer disposed between the one or more memory devices and the surrounding bulk material layer;
a semiconductor layer disposed on the one or more memory devices and the bulk material layer, the semiconductor layer is bonded with the one or more memory devices through a bonding interface layer; and
a plurality of micro bumps disposed on the semiconductor layer.

2. The semiconductor device assembly of claim 1, wherein the one or more memory devices include high bandwidth memory (HBM) cubes each having a plurality of memory dice vertically stacked.

3. The semiconductor device assembly of claim 2, wherein the plurality of memory dice of the one or more HBM cubes are bonded to each other through corresponding conductive bonding layers.

4. The semiconductor device assembly of claim 1, wherein the semiconductor layer comprises redistribution layers or signal routing layers, and wherein the redistribution layers of the semiconductor layer are configured to redistribute signals from the one or more memory devices to corresponding micro bumps.

5. The semiconductor device assembly of claim 4, wherein the signal routing layers of the semiconductor layer are configured to manage data signal, address signal, and control signal passing through the one or more memory devices.

6. The semiconductor device assembly of claim 1, wherein the semiconductor layer further comprises a plurality of transistors and passive devices.

7. The semiconductor device assembly of claim 1, wherein the bulk material layer is made of materials comprising silicon, germanium, gallium arsenide, silicon carbide, gallium nitride, and III-V semiconductors.

8. The semiconductor device assembly of claim 1, wherein the insulating layer is made of materials comprising silicon dioxide, silicon nitride, silicon carbide, silicon oxycarbide, silicon oxynitride, high-K dielectric materials, or a combination thereof.

9. The semiconductor device assembly of claim 1, further comprising a molding material that encapsulates the bulk material layer and the semiconductor layer.

10. The semiconductor device assembly of claim 1, further comprising a plurality of under bump metallization layers disposed on the semiconductor layer, each one of the plurality of under bump metallization layers being underneath corresponding micro bumps.

11. A semiconductor device assembly, comprising:
a semiconductor layer comprising transistors, passive devices, redistribution layers, and signal routing layers;
one or more memory devices disposed on the semiconductor layer;
a bulk material layer disposed on the semiconductor layer, the bulk material surrounding edges of each one of the one or more memory devices;
an insulating layer disposed between the one or more memory devices and surrounding bulk material layer; and
a plurality of micro bumps disposed under the semiconductor layer.

12. The semiconductor device assembly of claim 11, further comprising one or more conductive bonding layers through which the one or more memory devices are bonded to the semiconductor layer.

13. The semiconductor device assembly of claim 11, further comprising a plurality of under bump metallization layers disposed under the semiconductor layer, the plurality of micro bumps being electrically connected to the semiconductor layer through the plurality of under bump metallization layers.

14. The semiconductor device assembly of claim 13, wherein the plurality of under bump metallization layers are made of materials comprising titanium, chromium, nickel, titanium tungsten, copper, gold, or their alloys.

15. A method of semiconductor device assembly, comprising:
bonding a semiconductor device wafer on a carrier wafer to form a flat interface therebetween, the semiconductor device wafer having a frontside surface facing towards the carrier wafer;
thinning the semiconductor device wafer from its backside surface;
patterning the semiconductor device wafer from its backside surface and removing bulk material of the semiconductor device wafer to expose a semiconductor layer that is disposed on the frontside surface of the semiconductor device wafer;
forming a bonding layer on the exposed surface of the semiconductor layer;
bonding one or more memory devices on the exposed semiconductor layer; and
filling insulating material into gaps between each of the one or more memory devices and surrounding bulk material layer of the semiconductor device wafer.

16. The method of claim 15, further comprising:
grinding the insulating material on the backside of the semiconductor device wafer to form a flat surface;
singulating the semiconductor device assembly through the bulk material layer of the semiconductor device wafer;
removing the carrier wafer; and
mounting the singulated semiconductor device assembly on a substrate.

17. The method of claim 16, further comprising:
depositing a under bump metallization layer on the semiconductor layer;
patterning the under bump metallization layer; and
forming a plurality of micro bumps on the patterned under bump metallization layer.

18. The method of claim 17, further comprising encapsulating the bulk material layer and the semiconductor layer by a molding material.

19. The method of claim 15, wherein bonding of the semiconductor device wafer on the carrier wafer is conducted by a frontside to frontside (F2F) fusion bonding process.

20. The method of claim 15, wherein bonding of one or more memory devices on the semiconductor layer is conducted by a hybrid bonding process.
